(19) United States
(12) Patent Application Publication
(10) Pub. No.: US 2009/0238954 A1
(43) Pub. Date: Sep. 24, 2009

(54) LARGE AREA THIN FILM CAPACITORS ON METAL FOILS AND METHODS OF MANUFACTURING SAME

(76) Inventors: SEIGI SUH, Cary, NC (US); Esther Kim, Cary, NC (US); William Borland, Chapel Hill, NC (US); Cengiz Ahmet Palanduz, Durham, NC (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 12/051,931

(22) Filed: Mar. 20, 2008

(51) Int. Cl. B05D 5/12; H01G 7/00; H05K 3/30

(52) U.S. Cl. 427/79; 29/25.41; 29/832

(57) ABSTRACT

Disclosed are a method of making a dielectric on a metal foil, and a method of making a large area capacitor that includes a dielectric on a metal foil. A dielectric precursor layer and the base metal foil are prefired at a prefiring temperature in the range of 350 to 650° C. in a moist atmosphere that also comprises a reducing gas. The prefired dielectric precursor layer and base metal foil are subsequently fired at a firing temperature in the range of 700 to 1200° C. in an atmosphere having an oxygen partial pressure of less than about 10⁻⁶ atmospheres to produce a dielectric. The area of the capacitor made according to the disclosed method may be greater than 10 mm², and subdivided to create a multiple individual capacitor units that may be embedded in printed wiring boards. The dielectric is typically comprised of crystalline barium titanate or crystalline barium strontium titanate.

### TECHNICAL FIELD

The present invention pertains to capacitors that may be embedded in printed wiring boards, and more particularly to capacitors that include a thin film dielectric formed on a metal foil.

### RELATED ART

Semiconductor devices including integrated circuits (IC) are operating at increasingly higher frequencies and higher data rates and at lower voltages. Noise in the power and ground (return) lines and the need to supply sufficient current to accommodate the faster circuit switching has become an increasingly important problem. In order to provide low noise and stable power to the IC, low impedance in the power distribution system is required. The higher operating frequencies (higher IC switching speeds) mean that voltage response times to the IC must be faster. Lower operating voltages require that allowable voltage variations (ripple) and noise become smaller. For example, as a microprocessor IC switches and begins an operation, it calls for power to support the switching circuits. If the response time of the voltage supply is too slow, the microprocessor will experience a voltage drop or power droop that will exceed the allowable ripple voltage and noise margin and the IC will trigger false gates. Additionally, as the IC powers up, a slow response time will result in power overshoot.

Power droop and overshoot are maintained within the allowable limits by the use of capacitors that provide or absorb power in the appropriate response time. Capacitors are generally placed as close to the IC as possible to improve their performance. In conventional circuits, impedance has been reduced by the use of surface mount technology (SMT) capacitors interconnected in parallel. Conventional designs have capacitors surface mounted on the printed wiring board (PWB) clustered around the IC. Large value capacitors are placed near the power supply, mid-range value capacitors at locations between the IC and the power supply and small value capacitors very near the IC. Large numbers of capacitors, interconnected in parallel, are often needed to reduce power system impedance. This requires complex electrical routing which leads to inductance. As IC operating frequencies increase and operating voltages continue to drop, power increases and higher capacitance has to be supplied at increasingly lower inductance levels.

A high capacitance density, thin-film ceramic capacitor can be embedded in the PWB package onto which the IC is mounted. A single layer ceramic capacitor directly under the IC can reduce the inductance and provide the capacitance necessary to satisfy the IC requirements. Such a capacitor in the PWB can provide capacitance at a significantly quicker response time and lower inductance than surface mounted capacitors.

Embedment of high capacitance, ceramic film capacitors in printed wiring boards is known. Capacitors are initially formed on metal foils by depositing a capacitor dielectric material on the foil and firing it at an elevated temperature. A top electrode is formed on the dielectric to form a fired-on-foil capacitor structure. The foil is then bonded to an organic laminate structure to create an inner layer panel wherein the capacitor is embedded in the panel. The inner layer panel is then stacked with other inner layer panels and connected by interconnection circuitry, and the stack of panels form a multi-layer printed wiring board.

High capacitance density may be achieved by use of a thin dielectric with a high permittivity or dielectric constant (K). High dielectric constant thin-films of less than 1 micrometer in thickness can be deposited onto a metal foil by sputtering, laser ablation, chemical vapor deposition, and chemical solution deposition. Initial deposition is either amorphous or crystalline depending upon deposition conditions. Amorphous compositions have relatively low K (approximately 20) and have to be fired at high temperatures to induce crystallization and produce the desired high K phase. The high K phase in barium titanate based dielectrics can only be achieved when grain sizes exceed 0.1 micron and so firing temperatures as high as 900° C. may be used.

Chemical solution deposition (CSD) and sputtering techniques for fired-on-foil thin-film capacitor fabrication for embedment into printed wiring boards are disclosed in U.S. Pat. No. 7,029,971 to Borland et al. CSD techniques have been shown to produce high capacitance density films of less than 1 square micrometer on metal foils. CSD techniques are desirable due to their simplicity and low cost. Embedded capacitors in printed wiring boards made by such techniques, however, are subject to additional requirements other than the capacitance density. In particular, once the capacitors are embedded they cannot be replaced like surface mounted capacitors. Accordingly, 100% embedded capacitor yield is required for each printed wiring board to function as designed. If one embedded capacitor in the printed wiring board does not function, the board has to be discarded. Achieving 100% embedded capacitor yield is especially troublesome where it is desirable for a large number of embedded capacitors to occupy the area under a semiconductor such as an IC mounted on the printed wiring board. A single IC may require hundreds of embedded capacitors. There is a need for process by which large numbers of embedded capacitor units with 100% yield can be obtained.

### SUMMARY

A method of making a dielectric is disclosed. The disclosed method comprises the steps of providing a base metal foil, and forming a dielectric precursor layer over the base metal foil. The dielectric precursor layer and base metal foil are prefired at a prefiring temperature in the range of 350 to 650° C. in a moist atmosphere comprising a reducing gas. The prefired dielectric precursor layer and base metal foil are subsequently fired at a firing temperature in the range of 700 to 1200° C. in an atmosphere having an oxygen partial pressure of less than about 10⁻⁶ atmospheres to produce a dielectric. In one embodiment of the disclosed method, the firing results in a dielectric comprising crystalline barium titanate or crystalline barium strontium titanate.

In the disclosed method of making a dielectric, the dielectric precursor layer is most typically formed over the base metal foil by coating a film of a dielectric precursor solution on the base metal foil and drying the dielectric precursor solution. In one embodiment of the method disclosed, the forming of a dielectric precursor layer over the base metal foil comprises the steps of coating a first layer of a dielectric precursor solution on the base metal foil, drying the first layer of dielectric precursor solution at a temperature between 150 and 300° C. to form a first dried dielectric precursor layer, coating an additional dielectric precursor solution layer over the dried first dielectric precursor layer, drying the additional dielectric precursor solution layer at a temperature between 150 and 300° C. to form an additional dried dielectric precursor layer over the first dried dielectric precursor layer.

In one disclosed embodiment, the prefiring temperature is in the range of 350 to 500° C. In another disclosed embodiment, the reducing gas in the prefiring atmosphere is selected from H₂ and CO. The base metal foil is typically comprised of one or more metals selected from copper, nickel, invar, stainless steel and alloys thereof.

In another embodiment of the disclosed method, after the prefiring of the dielectric precursor layer, an additional dielectric precursor layer is formed over the prefired dielectric precursor layer, and the additional dielectric precursor layer is prefired at a temperature in the range of 350 to 650° C. in an atmosphere having a partial pressure of water vapor of at least about 0.02 atmospheres and also comprising a reducing gas.

Also disclosed is a method for making a capacitor. According to the disclosed method, a dielectric is formed on a metal foil as described above, and a second conductive layer is formed over the dielectric, wherein the metal foil, the dielectric, and the second conductive layer form the capacitor. The area of the capacitor made according to the disclosed method may be greater than 10 mm², and may be greater than 80 mm², and may even be greater than 400 mm², and may even be greater than 2500 mm². The metal foil and the second conductive layer of the capacitor may be selectively etched to create a plurality of individual capacitor units wherein each of the individual capacitor units can function as a separate capacitor. The plurality of individual capacitor units may comprise more than twenty individual capacitor units embedded in a printed wiring board or even more than one hundred or even more than five hundred individual capacitor units embedded in a printed wiring board.

### BRIEF DESCRIPTION OF THE DRAWINGS

According to common practice, the various features of the drawings discussed below are not necessarily drawn to scale. Dimensions of various features and elements in the drawings may be expanded or reduced to more clearly illustrate the embodiments of the invention. The detailed description will refer to the following drawings, wherein like numerals refer to like elements, and wherein:

FIG. 1 is a block diagram illustrating a process for preparing a dielectric precursor solution that will be used to form a dielectric according to the methods disclosed herein.

FIG. 2 is a block diagram of a method suitable for forming a capacitor on metal foil according to the methods disclosed herein.

FIG. 3 is a series of X-ray diffraction patterns described in Example 3 showing the effects of different prefire temperatures under moist reducing atmospheres on dried dielectric precursor films on copper foil.

FIG. 4 is a plot showing the capacitance density of 10 mm by 10 mm capacitors on copper foil that were prefired at three different temperatures under a moist reducing atmosphere and were subsequently fired at 900° C., as described in Example 3.

FIG. 5 is a graph showing capacitance density and dissipation factor as a function of voltage of a representative sample of barium titanate on nickel foil that was prefired at 450° C. under a moist reducing atmosphere followed by firing at 900° C. under a partial pressure of oxygen of approximately 10⁻¹⁴ atmospheres followed by a re-oxidation at 600° C. under a partial pressure of oxygen of approximately 10⁻⁶ atmospheres as described in Example 5.

FIG. 6 is a plot showing capacitance density of 3 mm by 3 mm (9 mm²), 5 mm by 5 mm (25 mm²), and 10 mm by 10 mm (100 mm²) capacitors on copper foil that were prefired at 450° C. under a moist reducing atmosphere and then fired at 950° C. under a partial pressure of oxygen of approximately 10⁻¹⁴ atmospheres followed by a re-oxidation at 600° C. under a partial pressure of oxygen of approximately 10⁻⁶ atmospheres as described in Example 8.

### DETAILED DESCRIPTION

### Definitions

The following definitions are used herein to further define and describe the disclosure.

As used herein and recited in the claims, the term “a” includes the concepts of “at least one” or “one or more than one”.

As used herein, “drying” refers to removing the solvent from a deposited dielectric precursor solution. Drying may be achieved by heating the deposited precursor solution to a temperature of between approximately 100° C. and 300° C. to effect solvent removal.

As used herein, “base metal foil” refers to metal foils that do not comprise precious metal and as such, will oxidize if subjected to elevated temperatures under ambient conditions.

As used herein, “prefiring” refers to heating or baking dielectric precursor layers for a short period of time at a temperature of between approximately 350° C. and 650° C. to remove the organic content of the dried dielectric precursor by decomposition, hydrolysis and/or pyrolysis.

As used herein, the terms “high dielectric constant”, “high Dk” and “high permittivity” are interchangeable and refer to dielectric materials that have a bulk dielectric constant above 500.

As used herein, the terms “firing”, “annealing” and “sintering” are interchangable and refer to processing the dielectric at an elevated temperature, such as greater than 700° C.

As used herein, the terms “re-oxygenating” the dielectric and “re-oxidizing” the dielectric are interchangeable and refer to processing the dielectric at a temperature that is below that used for firing the dielectric in an atmosphere that is richer in oxygen than that used in the firing process.

As used herein, “capacitance density” refers to the measured capacitance of the capacitor divided by the common area of the electrodes of the capacitor. Capacitance density is related to the dielectric constant by the relationship:

C/A=0.885K/t

where C/A is the capacitance density in nano Farads (nF) divided by the common electrode area expressed in square centimeters (cm²); K is the dielectric constant; t is the dielectric thickness in micrometers (microns); and 0.885 is a constant (permittivity of free space).

As used herein, “embedded” refers to incorporating an electronic part, such as a capacitor, into a printed wiring board.

Described herein is a method of making a dielectric on a base metal foil. Also described is a method of making a capacitor that includes a dielectric on a base metal foil. Also described herein is a method of making a large area fired-on-foil capacitor with a high capacitance density. Large area capacitors constructed according to the method disclosed herein can be embedded into inner-layer panels and sub-divided into multiple capacitors units, which may in turn be incorporated into printed wiring boards.

Large area capacitors can be tested and only “known good” capacitors will be placed on the printed wiring board where desired. A known good large area capacitor can subsequently be divided up into multiple capacitor units, as for example by patterning the conductive layers of the known good large area capacitor by etching. One hundred percent of the multiple individual capacitor units that result will also be good because they are made from the division of a known good large area capacitor. This is especially useful for printed wiring boards that are small, such as interposer devices, where dimensions are in the order of 10 mm by 10 mm to 30 mm by 30 mm.

The fabrication of large area CSD thin-film capacitors on metal foil has been limited by the defect density in the dielectric thin-film caused, for example, by the presence of cracks, porosity, voids, and pinholes. Such defects have limited the size of such capacitors to less than approximately one to three square millimeters. Defects in the dielectric may form for a variety of reasons, such as, for example, the effect of the underlying metal foil, dust particles in the fabrication area, inadequate densification of the dielectric, and defects or vacancies in the molecular structure. A high level of densification of the dielectric wherein any porosity in the film is isolated, is generally accepted as being required to achieve high yield in large area capacitors. Firing a CSD dielectric precursor deposit on metal foil, however, restricts the shrinkage of the dielectric to the “z” or vertical dimension when sintering takes place. This and the high level of refractoriness exhibited by high dielectric constant materials, makes achieving functioning large area capacitors difficult.

Disclosed is a method of making a dielectric, comprising the steps of providing a base metal foil, forming a dielectric precursor layer over the base metal foil, prefiring the dielectric precursor layer and base metal foil, firing the prefired dielectric precursor layer and base metal foil to produce a dielectric, and optionally re-oxygenating the dielectric. Prefiring the dielectric precursor layer and base metal foil is accomplished at a prefiring temperature in the range of 350 to 650° C. in an atmosphere having a partial pressure of water vapor of at least 0.02 atmospheres and an oxygen partial pressure of less than about 10⁻⁶ atmospheres. Firing the prefired dielectric precursor layer and base metal foil may be accomplished at a firing temperature in the range of 700 to 1200° C. in an atmosphere having an oxygen partial pressure of less than about 10⁻⁶ atmospheres, the exact firing temperature and atmosphere depending on the underlying metal foil. Re-oxygenating the fired dielectric can be performed at a temperature below the firing temperature.

The base metal foil may be of a type generally used in the production of fired on foil capacitors. For example, the foil may be copper (Cu) or its alloys, copper-invar-copper, invar, nickel (Ni), nickel-coated copper, stainless steel, or other metals or metal alloys that have melting points in excess of the firing temperature for thin-film dielectrics. The metallic foil serves as a substrate on which the dielectric is built, and it also serves as a “bottom” electrode in a finished capacitor. Preferred base metal foils include foils comprised predominantly of copper or nickel. Copper foils are desirable due to their low cost and ease of handling. The thickness of the foil may be in the range of, for example, between 1 and 100 micrometers, preferably between 3 and 75 micrometers. Examples of suitable copper foil are PLSP grade 1 ounce copper foil that is 36 micrometer thick or ½ ounce copper foil that is 18 micrometers thick, obtainable from Oak-Mitsui. Examples of suitable nickel foil is Nickel 201 foil that is 76.2 micrometer thick or that is 25.4 micrometer thick, obtainable from All Foils Inc.

If the metallic foil is received from the vendor in clean condition, is carefully handled, and is promptly used, cleaning may not be necessary and the bare untreated metallic foil may be suitable for use in the disclosed method. The metal foil may be cleaned. Cleaning may be accomplished by use of a solvent, such as isopropanol. The foil may also be cleaned by briefly etching the foil, as for example by etching a copper foil for 30 seconds in a dilute solution of copper chloride in hydrochloric acid. The etching solution may be diluted approximately 10,000 times from its concentrated form. The cleaning process removes the excess oxide layer, fingerprints and other accumulated foreign matter from the foil. The foil is preferably not treated with organic addititves, which are sometimes applied in order to enhance adhesion of a metallic substrate to epoxy resins, because the organic additives may degrade the dielectric.

In the method disclosed herein, a dielectric is formed over the base metal foil. Preferred dielectrics are comprised of materials with high dielectric constants such as perovskites of the general formula ABO₃ in which the A site and B site can be occupied by one or more different metal cations. For example, high K is realized in crystalline barium titanate (BT), lead zirconate titanate (PZT), lead lanthanum zirconate titanate (PLZT), lead magnesium niobate (PMN) and barium strontium titanate (BST). In the method described herein, barium titanate (BaTiO₃) based materials are preferred for the dielectric layer because barium titanate based materials have high dielectric constants and are lead free.

Tetravalent metal cations such as zirconium (Zr), hafnium (Hf), tin (Sn) and cerium (Ce) having the preferred oxide stoichiometry of MO₂ may partially substitute for titanium in the dielectric material. These metal cations smooth the temperature-dependence of permittivity in the dielectric by “pinching” (shifting) the three phase transitions of BaTiO₃ closer to one another in temperature space. Divalent cations having the preferred oxide stoichiometry of MO, where M is an alkaline earth metal (e.g., calcium [Ca], strontium [Sr] or magnesium [Mg]), may partially substitute for barium as these can shift the dielectric temperature maxima to lower temperatures, further smoothing the temperature-dependent response of the dielectric.

Dopant cations may be also be added to the barium titanate to modify the dielectric characteristics. For example, small quantities of dopant rare earth cations having the preferred oxide stoichiometry of R₂O₃, where R is a rare earth cation (e.g., yttrium [Y], holmium [Ho], dysprosium [Dy], lanthanum [La] or europium [Eu]) may be added to the composition to improve insulation resistance and reliability of the resulting dielectric. Small atomic radii cations of the oxide stoichiometry MO such as calcium (Ca), or magnesium (Mg) as well as transition metal cations such as nickel (Ni), manganese (Mn), chromium (Cr), cobalt (Co) or iron (Fe) may be used to dope the titanium site with “acceptors” to improve insulation resistance of the dielectric. The above-described dopants or mixtures of these may be used in various concentrations. Acceptor doping with as little 0.002 atom percent may be used to create high dielectric constant thin film dielectrics that exhibit low dielectric losses and low leakage currents under bias.

The dielectric layer should have a physically robust dielectric thickness in the range of about 0.5-1.5 micrometers (μm) with a capacitance density of approximately greater than 0.5 microFarads per square centimeter (μF/cm²), and typically between 0.5 and 2.0 μF/cm².

Chemical solution deposition (CSD) techniques may be used to form the dielectrics according to the method disclosed herein. Other deposition methods, such as sputtering, may also be used but CSD techniques are desirable due to their simplicity and low cost. The chemical precursor solution from which a BaTiO₃ based dielectric can be prepared may comprise barium acetate, titanium isopropoxide, acetylacetone, acetic acid, and diethanolamine. Other chemistries are feasible. A 0.38 mol solution of “undoped” or pure barium titanate precursors may be prepared from the following:

| | | |
|---|---|---|
| Barium acetate | 2.6 | g |
| Titanium isopropoxide | 2.9 | ml |
| Acetylacetone | 2.0 | g |
| Acetic acid | 22.1 | g |
| Diethanolamine | 0.3 | g |

The precursor solution may or may not contain a dopant source or sources of other substitutions for barium or titanium as previously discussed. For example, an appropriate amount of manganese acetate tetrahydrate may be used to add a desired amount of manganese to the precursor solution. For calcium, calcium nitrate tetrahydrate or calcium acetate may be used. For a stable dielectric precursor solution, the above chemicals should be free of water. Water de-stabilizes the precursor composition, resulting in precipitation of titanium oxide. It is therefore important to prepare and deposit the dielectric precursor solution in relatively low humidity environments, such as less than about 40% relative humidity. Once the dielectric precursor solution has been fully deposited on a foil and dried, it is less susceptible to humidity.

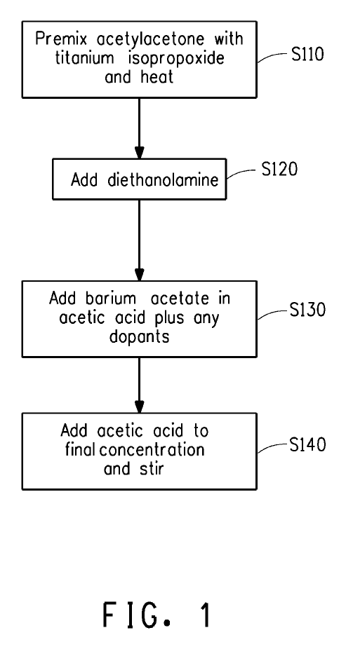

FIG. 1 is a block diagram illustrating a process for preparing the dielectric precursor solution that will be used to form a dielectric according to the method disclosed herein. In step S110, the titanium isopropoxide is premixed with the acetylacetone and heated. The premix can be done in, for example, a PYREX® container, and heating may take place on a hot plate with a surface temperature of about 90° C. In step S120, the diethanolamine is added to the Ti isopropoxide/acetylacetone mixture. In step S130, a solution of the barium acetate is prepared in some of the acetic acid and added into the container and stirred. In step S130, if any dopant is to be introduced, the dopant solution (such as manganese acetate tetrahydrate or calcium acetate hydrate, for example) can also be added in the appropriate concentration and the mixed solution is stirred. In step S140, the remainder of the acetic acid is added to the solution to yield a 0.38 mol concentration of the barium titanate precursor. The precursor solution is now suitable for deposition or further dilution with acetic acid if a more dilute concentration is desired.

Variants of the acetylacetone components and the acetic acid used for dilution in the above-described precursor solution may also be used. For example, acetylacetone may be substituted by an alkoxyalcohol such as 2-methoxyethanol, 2-ethoxyethanol and 1-methoxy-2-propanol. Diethanolamine may be substituted by other ethanolamines such as triethanolamine, and monoethanolamine or alcohols such as methanol, ethanol, isopropanol, and butanol, for example. Titanium isopropoxide may also be substituted by titanium butoxide.

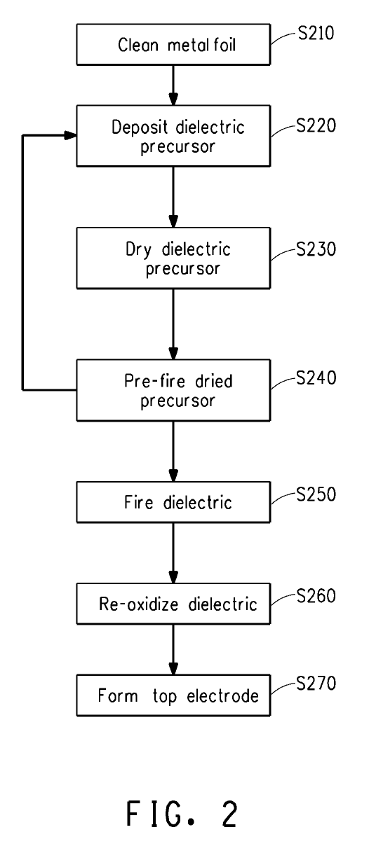

FIG. 2 is a block diagram showing a method suitable for forming a dielectric precursor layer on a base metal foil according to the disclosure. The dielectric precursor layer may be formed using a dielectric precursor solution such as the precursor solutions discussed above with reference to FIG. 1. In step S210, a base metal foil is provided. The base metal foil may one of the metal foils described above, such as a foil comprised predominantly of copper or nickel. In step S220, the dielectric precursor solution is deposited over the base metal foil. In the case of copper foil, for example, the drum side (or “smooth side”) of the copper foil would be the side of choice. The deposition process of step S220, may be, for example, rod coating, spin coating, dip coating or spray coating. If spin coating is used, a suitable rotation time and speed are 30 seconds at 3000 revolutions per minute. Other conventional coating methods are also practical. The coating process is set up to deposit a dielectric precursor layer of approximately 50-150 nano-meters in thickness.

In step S230, the dielectric precursor solution is dried to form a dielectric precursor layer on the base metal foil. Drying may be performed, for example, at a temperature of between 100° C. and 300° C. in air for five to ten minutes and more typically at a temperature of 150° C. to 250° C. Drying may be accomplished by placing the coated foil on a hot plate. Drying evaporates the solvents in the precursor solution.

In step S240, the dried dielectric precursor layer and base metal foil are prefired. Prefiring the dielectric precursor layer and base metal foil is accomplished at a prefiring temperature in the range of 350 to 650° C. Prefiring is preferably repeated after each layer has been dried but prefiring may be undertaken for two or more dried dielectric precursor layers at one time depending upon dried dielectric precursor layer thickness.

Prefiring of the dielectric precursor layer and underlying base metal foil is conducted in a moist reducing gas atmosphere. The presence of moisture in the gas atmosphere promotes organic decomposition and removal by hydrolysis. A moist atmosphere may be achieved by bubbling a gas through a water bath prior to entering the prefire furnace. Bubbling a gas through a water bath at 20° C. will create a gas atmosphere with a preferred partial pressure of water vapor of at least 0.02 atmospheres. Typically, the partial pressure of water vapor in the prefiring atmosphere will be in the range of 0.02-0.10 atmospheres, and more typically in the range of 0.02-0.04 atmospheres. Higher water bath temperatures will create somewhat higher water vapor levels. A small amount of a reducing gas, such as hydrogen gas, should also be present in the prefiring atmosphere. The small amount of the reducing gas insures that the underlying base metal foil is not oxidized during the organic removal. Hydrogen may be safely added to the nitrogen by using forming gas (99% nitrogen and 1% hydrogen mix). Sufficient forming gas is added to maintain the partial pressure of oxygen (PO₂) in the prefiring atmosphere at less than about 10⁻⁸ atmospheres. A variety of moist gas mixtures may be used. For example, carbon monoxide may substitute for hydrogen and carbon dioxide or argon may substitute for nitrogen. Small amounts of air may also be included.

Prefiring of the dried dielectric precursor layer removes the residual organic material or polymer content of the dried dielectric precursor layer by decomposition and/or hydrolysis or pyrolysis, thus, converting the dried dielectric precursor layer to an amorphous inorganic layer. The prefiring step is conducted under conditions that remove the organic content from the dielectric precursor layer while minimizing the initiating of crystallization of the dielectric precursor material, such as barium titanate. Crystallization of barium titanate during the prefiring process occurs at maximum initiation sites due to the relatively low prefiring temperature. This creates micro-crystalline grains which will inhibit grain growth during the firing step. If some minor level of crystallization is acceptable, prefiring of a barium titanate based dielectric precursor layers may be performed at a temperature anywhere in the range from approximately 350° C. to a temperature less than about 650° C. If initiation of crystallization is to be avoided, the prefiring of a barium titanate based dielectric precursor layers should be performed at a temperature in the range of approximately 400° C. to less than about 500° C. During prefiring, the period at peak temperature is approximately 10 to 20 minutes.

Prefiring of the deposited dielectric precursor layers improves the green density of each dielectric precursor layer which shrinks the thickness of the dielectric precursor layers. Consecutive precursor layer deposition, drying and prefiring steps may be used to coat the base metal foil substrate to the desired thickness. Ten to twelve coating steps, for example, may be used to produce a final prefired dielectric precursor thickness of 1 micrometer. Removing the organic content during each prefiring allows for shrinkage of the precursor layers, thereby improving its particle packing or “green” density. Improving the green density at this stage allows for improved densification of the dielectric on firing. This means the level of shrinkage necessary to achieve high densification during firing of the multiple layers will be less than if no prefiring had been practiced. The prefiring of deposited dielectric precursor layers in a moist, low oxygen atmosphere removes residual organic and polymer from each deposited layer, and makes a higher densification of the dielectric possible when the multiple layers are fired, and with far fewer defects than was previously thought possible. The high degree of densification and relative absence of defects obtained with the disclosed method enables the generation of higher yield large area dielectrics and capacitors.

In step S250, the dielectric precursor is fired to produce the dielectric. Firing of the dielectric may alternatively be referred to as an annealing or sintering step. Temperatures for firing the dielectric may range from 700° C. to 1200° C. depending on the melting point of the underlying metal foil and the dielectric micro-structure desired. For example, firing a dielectric on nickel foil may be undertaken at temperatures as high as 1200° C. but for copper foil, firing is limited to about 1050° C. The firing period at peak temperature is typically between 10 and 30 minutes but could be shorter or longer depending on the dielectric precursor material used. During the ramp up of temperature during firing, the dielectric crystallizes and further heating promotes grain growth resulting in higher dielectric constants, and densification of the dielectric.

Firing of the dielectric is conducted in a low oxygen partial pressure environment to protect the underlying base metal foil from oxidation. The exact atmosphere required will depend upon the temperature and the thermodynamics and kinetics of oxidation of the underlaying metal foil. Atmospheres that fully protect the metal foil from oxidation can be thermodynamically derived from standard free energy of formation of oxides as a function of temperature calculations or diagrams as disclosed in “F. D. Richardson and J. H. E Jeffes, J. Iron Steel Inst., 160, 261 (1948)”. For example, using copper as the underlying metallic foil, firing at 700° C., 900° C. and 1050° C. would require partial pressures of oxygen (PO₂) of approximately less than 4×10⁻¹¹, 3.7×10⁻⁸, and 1.6×10⁻⁶ atmospheres, respectively, to protect the copper from oxidation. For nickel, these values would be less than about 5×10⁻¹⁸, 5×10⁻¹³, and 1.0×10⁻¹⁰ atmospheres, respectively for firing at 700° C., 900° C. and 1050° C. When firing the dielectric, it is desirable to have the highest PO₂ level feasible in order to minimize oxygen vacancy and free electron formation due to reduction of the dielectric. The PO₂ level should be set at the highest level possible that will not cause significant oxidation of the metal foil. A small amount of oxidation of the metal foil may be acceptable and, therefore, the PO₂ level for the atmosphere during firing of the dielectric may be higher than that calculated to entirely protect the foil from oxidation. However, if the level of oxidation is too high, a thick oxide layer will be formed on the underlying metal foil which reduces the effective dielectric constant of the dielectric. The optimum oxygen partial pressure depends on the metal foil, dopant type and concentration if used, and the firing temperature. For example, when the foil is copper, the rate of oxidation is relatively fast and the oxide thickness grows in a linear fashion with time and temperature, so the PO₂ level is generally set at that required to maintain a non-oxidized surface, i.e., from approximately 10⁻⁶ to 10⁻¹² atmospheres depending on the temperature as described above. For a nickel foil, the rate of oxidation is slower than copper, and therefore, the PO₂ level of the firing atmosphere can be in the range of 10⁻⁶ to 10⁻¹⁰ atmospheres.

The desired oxygen partial pressure in the furnace may be achieved by use of suitable gas combinations or vacuum. Such combinations include pure nitrogen, nitrogen/forming gas/water mixtures, nitrogen/forming gas mixtures, nitrogen/forming gas/carbon dioxide mixtures, carbon dioxide/carbon monoxide mixtures, etc. A typical forming gas is a mixture of 99% nitrogen and 1% hydrogen gas. After firing the foil and dielectric are allowed to cool.

In step S260 shown in FIG. 2, the dielectric is optionally re-oxygenated. The high firing temperature and the low oxygen reducing atmosphere present during firing may result in a dielectric with reduced oxygen in the lattice of the dielectric. This tends to result in a high concentration of oxygen vacancies, which leads to high leakage and poor long-term reliability when the dielectric is used in a capacitor. However, re-oxidation can put oxygen back into the lattice and generally occurs at a lower temperature and at higher oxygen contents than used during the firing process. A suitable re-oxidation process depends on the underlying metal foil but may be about 30 minutes at a temperature of between 400° C. and 700° C. in an atmosphere that has a partial pressure of oxygen in the range of that of ambient air to 10⁻⁶ atmospheres. For a dielectric on copper foil, reoxidation will require an atmosphere that avoids oxidation of the foil. The exact atmosphere required depends on the temperature and may range from an oxygen partial pressure of 10⁻² to 10⁻⁶ atmospheres. For a dielectric on nickel foil, a re-oxidation in air at 400-500° C. for 5 to 10 minutes may be used without severe oxidation of the foil due to the slow kinetics of oxidation of nickel at these temperatures. Reoxidation may be incorporated into the cool down zone of the furnace after firing by converting the nitrogen/forming gas mixture to a more oxidizing atmosphere. For example, the forming gas may be switched off at 600° C. allowing just nitrogen to flow through the furnace. A nitrogen atmosphere will result in a partial pressure of oxygen of approximately 10⁻⁶ atmospheres due to its impurity oxygen content. If the firing of the dielectric is undertaken under less severe reducing conditions, such as under pure nitrogen and/or if the dielectric is doped with acceptor dopants, re-oxidation may be dispensed with. With acceptor doping, conduction electrons are trapped by the acceptor dopant so that a decrease in insulation resistance and increase in dielectric losses are suppressed.

The disclosed process for making a dielectric provides a fired on foil dielectric with desirable physical and electrical properties. One desirable physical property is a dense microstructure. Another desirable property is the very low defect rate which makes it possible to make large area capacitors, for example 10 mm by 10 mm capacitors with high yield. Another desirable physical property is the resultant dielectric grain sizes that are typically between 0.05 and 0.2 micrometers. One desirable electrical property resulting from the grain size is a capacitance density in excess of 0.5 μF/cm².

In step S270, top electrodes are formed over the resulting dielectric. The top electrode can be formed by, for example, sputtering, evaporation, chemical vapor deposition, electroless plating, printing or other suitable deposition methods. In one embodiment, a sputtered copper electrode is used. Other suitable materials for the top electrode include nickel, platinum, gold and palladium. The top electrode(s) may be plated with copper to increase thickness, if desired.

Large area capacitors on foil constructed according to the method disclosed herein can be tested and “known good capacitors” may be designated from their position on the foil. The foil may be further processed to pattern it, for example by etching techniques, and the foil may be diced or cut to separate individual “known good” capacitors on metal foil from non-functioning capacitors. Large area, known good capacitors may then be placed on the printed wiring board, where desired, by pick and place techniques. Each known good large area capacitor can be further processed to divide it up into multiple capacitor units, by patterning the top conductive layer by etching. One hundred percent of the multiple individual capacitor units that result will also be good because they are made from the division of a known good large area capacitor. This is especially useful for printed wiring boards that are small, such as interposer devices, where dimensions are in the order of 10 mm by 10 mm to 30 mm by 30 mm and embedded capacitors cover almost the entire area.

The following examples illustrate the favorable properties that can be obtained in dielectrics prepared according to the disclosed method, and the capacitors prepared according to the disclosed method.

### EXAMPLES

### Example 1

A 0.38 mol solution of “undoped” or pure barium titanate dielectric precursor solution was prepared according to the method of FIG. 1 from the following:

| | | |
|---|---|---|
| Barium acetate | 2.6 | g |
| Titanium isopropoxide | 2.9 | ml |
| Acetylacetone | 2.0 | g |
| Acetic acid | 22.1 | g |
| Diethanolamine | 0.3 | g |

The 0.38 mol barium titanate dielectric precursor solution was diluted to 0.3 mole concentration by use of additional acetic acid.

Capacitor on foil samples were prepared. For each sample, a first layer of the 0.3 mol dielectric precursor solution was deposited on to the drum side of a 2 inch by 2 inch ½ oz (18 micrometers thick) cleaned copper foil (obtained from Oak Mitsui) using spin coating. The coating speed was 3000 rpm. The precursor solution was then dried in air on a hot plate at 250° C. for 7 minutes. The dried thickness was approximately 0.1 micrometers. The process of spin coating deposition and drying was repeated until 6 layers had been deposited.

The multiple dried dielectric precursor layers on the copper foil were fired in a tube furnace with a 6 inch internal diameter tube. Firing was undertaken at 900° C. under an atmosphere consisting of a mixture of nitrogen and forming gas (99% nitrogen and 1% hydrogen) that had been bubbled through a water bath to moisten it prior to entering the furnace. The flow rates of the nitrogen and forming gas into the furnace were adjusted to give approximately 10 liters per minutes of nitrogen and 15-20 cubic centimeters (cc) per minute of forming gas to give between 0.015% to 0.02% hydrogen in nitrogen. A partial pressure of oxygen at the firing temperature of approximately 10⁻¹² atmospheres was measured by use of a zirconia cell placed inside the furnace. The ramp rate of the furnace during the heating phase was approximately 15° C. per minute. After firing, the dielectric was re-oxidized by exposing the dielectric to a partial pressure of oxygen of approximately 10⁻⁵ atmospheres at approximately 550° C.

Copper electrodes ranging in size from 1 mm by 1 mm to 10 mm by 10 mm were formed on the dielectric by sputtering copper through a mask. The 1 mm by 1 mm capacitors exhibited a high yield of greater than 90% and had a capacitance density of up to approximately 2 μF/cm². The capacitors with electrode sizes of equal to and greater than 3 mm by 3 mm exhibited cracking in the dielectric and were all shorted and had zero yield.

### Example 2

A 0.38 mol barium titanate dielectric precursor solution was prepared as described in Example 1, except that the dielectric precursor solution was doped with 0.07 mole % of manganese by adding 0.001 g of manganese acetate tetrahydrate to the barium acetate solution in the step S130 of the method shown in FIG. 1. The 0.38 mol barium titanate dielectric precursor solution was diluted to a 0.25 mole solution by use of additional acetic acid.

Several samples were prepared using the process as discussed with regard to FIG. 2. A first layer of the 0.25 mol dielectric precursor solution was deposited using rod coating on to a 5 inch by 5 inch, 25 micrometers thick, nickel foil obtained from All Foils. The precursor solution was then dried on a hot plate at 100° C. for 5 minutes. The dried dielectric precursor was pre-fired at 400° C. for 10 minutes in air. The ramp rate of the hot plate during the heating phase was approximately 10° C. per minute. The process of rod coating deposition, drying and pre-firing at 400° C. in air was repeated 11 more times after pre-firing of the first layer to give a total of 12 layers.

The multiple dried and pre-fired dielectric precursor layers on the nickel foil were fired in a six inch internal diameter tube furnace at 900° C. for 30 minutes at peak temperature. Firing was undertaken under an atmosphere consisting of nitrogen and forming gas (99% nitrogen 1% hydrogen). The flow rates of the nitrogen and forming gas into the furnace were adjusted to give approximately 10 liters per minutes of nitrogen and 15-20 cubic centimeters (cc) per minute of forming gas to give between 0.015% to 0.02% hydrogen in nitrogen. The partial pressure of oxygen at the firing temperature was measured to be approximately 10⁻¹⁴ atmospheres as measured by use of a zirconia cell in the furnace. The ramp rate of the furnace during the heating phase was approximately 15° C. per minute. During the cooling process, the forming gas supply to the furnace was switched off at 600° C. so that the dielectric was exposed to pure nitrogen at a partial pressure of oxygen of approximately 10⁻⁶ atmospheres to reoxidize the dielectric without oxidizing the underlying nickel foil.

After removal from the furnace, copper electrodes varying in size from 1 mm by 1 mm to 10 mm by 10 mm were formed on the dielectric by sputtering copper through a mask. All capacitor sizes had yields varying from 70%-90%. The capacitors exhibited capacitance densities of between approximately 0.5 and 1.0 μF/cm², but all had undesirable dissipation factors of greater than 100% and failed when any bias was applied.

### Example 3

A 0.38 mol barium titanate dielectric precursor solution was prepared as described in Example 1, except that the dielectric precursor solution was doped with 0.07 mole % of manganese by adding 0.001 g of manganese acetate tetrahydrate to the barium acetate solution in the step S130 of the method shown in FIG. 1.

Capacitor on foil samples were prepared. For each sample, a first layer of the doped 0.38 mol barium titanate dielectric precursor solution was deposited by spin coating on to the drum side of a 2 inch by 2 inch ½ oz (18 micrometers thick) cleaned copper foil obtained from Oak Mitsui. The coating speed was 3000 rpm. The precursor solution was then dried in air on a hot plate at 250° C. for 7 minutes. The dried precursor was then prefired for 10 minutes in a moist nitrogen/forming gas mixture that was created by bubbling a mixture of nitrogen and forming gas (99% nitrogen and 1% hydrogen) through a water bath at approximately 20° C. to create a gas atmosphere with a partial pressure of water vapor of about between 0.02 and 0.03 atmospheres. The hydrogen content in the nitrogen was adjusted to give between 0.015% to 0.02% hydrogen in nitrogen. Measurement of the partial pressure of oxygen at the temperatures used for the prefire process was not accurate, but the moist gas mixture was estimated to give a partial pressure of oxygen of approximately 10⁻¹² atmospheres. For each sample, the temperature for each prefiring was 450°, 550° C. or 650° C. A minimum of six samples were prefired at each temperature. The thickness of the dried and prefired dielectric precursor layer was approximately 0.1 micrometers. The process of spin coating deposition, drying and selected temperature prefiring for the sample was repeated nine more times after the first layer to give a total of 10 layers.

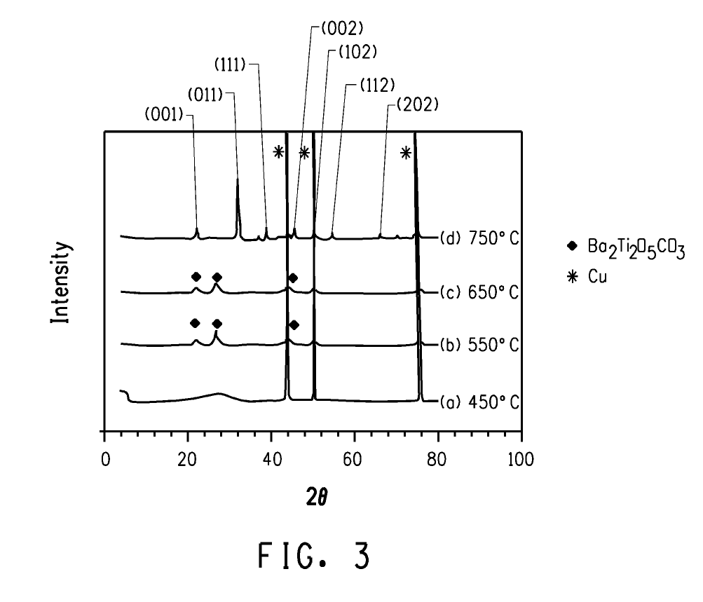

X-ray diffraction of the 10 layer baked and prefired films was undertaken to determine the temperature at which the residual organic and polymer phases are eliminated from the prefired dielectric precursor. As shown in FIG. 3, the crystallization of barium titanium oxylate (Ba₂Ti₂O₅CO₃) begins at approximately 550° C. indicating that organic removal occurs prior to this temperature.

The multiple dried and prefired dielectric precursor layers on the copper foil were fired in a six inch internal diameter tube furnace at 900° C. for 20 minutes at peak temperature. Firing was undertaken under a dry atmosphere consisting of a mixture of nitrogen and forming gas (99% nitrogen 1% hydrogen). The flow rates of the nitrogen and forming gas into the furnace were adjusted to give approximately 10 liters per minute of nitrogen and 15-20 cubic centimeters (cc) per minute of forming gas to result in between 0.015% to 0.02% hydrogen in nitrogen. The partial pressure of oxygen at the firing temperature was approximately 10⁻¹⁴ atmospheres as measured by use of a zirconia cell placed inside the furnace. The ramp rate of the furnace during the heating phase was approximately 15° C. per minute. The final fired dielectric thickness was approximately 0.7-0.8 micrometers. After firing, 10 mm by 10 mm “top” copper electrodes were formed on the dielectric by sputtering copper through a mask.

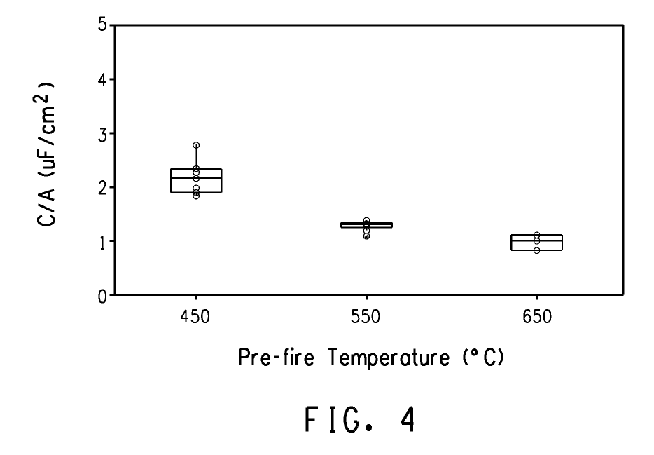

As shown in FIG. 4, the 10 mm by 10 mm capacitors exhibited capacitance densities of between approximately 1 and 2.5 μF/cm² depending on the prefire temperature and had a yield of 19 out of 21 parts (90%). The formation of the micro-crystalline barium titanate, as shown in FIG. 3, may explain the lower capacitance densities of the samples baked at 550° C. and 650° C. Dissipation factors of the capacitors varied between less than 10% for those samples prefired at 450° C. to over 40% for others due to a lack of a reoxidation process.

### Example 4

A 0.38 mol barium titanate dielectric precursor solution was prepared as described in Example 1, except that the dielectric precursor solution was doped with 0.07 mole % of manganese by adding 0.001 g of manganese acetate tetrahydrate to the barium acetate solution in the step S130 of the method shown in FIG. 1.

Capacitor on foil samples were prepared using the process as discussed with regard to FIG. 2. For each sample, a first layer of the dielectric precursor solution was deposited by rod coating on to the drum side of a 5 inch by 5 inch 1 oz (36 micrometers thick) cleaned copper foil obtained from Oak Mitsui. The dielectric precursor solution was then dried in air for 5 minutes at 100° C. followed by 7 minutes at 250° C. The dried dielectric precursor was then prefired for 10 minutes at 450° C. in a moist nitrogen/forming gas mixture that was created by bubbling a mixture of nitrogen and forming gas (99% nitrogen and 1% hydrogen) through a water bath at approximately 20° C. to create a gas atmosphere with a partial pressure of water vapor of about between 0.02 and 0.03 atmospheres. The hydrogen content in the nitrogen was adjusted to give between 0.015% to 0.02% hydrogen in nitrogen. Measurement of the partial pressure of oxygen at the temperatures used for the prefire process was not accurate, but the moist gas mixture was estimated to give a partial pressure of oxygen of approximately 10⁻¹² atmospheres. The thickness of the dried and prefired dielectric precursor layer was approximately 0.1 micrometers. The same process of rod coating deposition, drying and prefiring at 450° C. was repeated 7 more times after the first layer to give a total of 8 layers.

The multiple dried and prefired dielectric precursor layers on the copper foil were fired in a 6 inch internal diameter tube furnace at 900° C. for 20 minutes at peak temperature. Firing was undertaken under an atmosphere consisting of a mixture of nitrogen and forming gas (99% nitrogen and 1% hydrogen) that had been bubbled through a water bath to moisten it prior to entering the furnace. The flow rates of the nitrogen and forming gas into the furnace were adjusted to give approximately 10 liters per minute of nitrogen and 15-20 cubic centimeters (cc) per minute of forming gas to give between 0.015% to 0.02% hydrogen in nitrogen. The partial pressure of oxygen at the firing temperature was approximately 10⁻¹² atmospheres as measured by use of a zirconia cell placed inside the furnace. The ramp rate of the furnace during the heating phase was approximately 15° C. per minute. During the cooling process, the forming gas supply to the furnace was switched off at 600° C. so that the dielectric was exposed to pure nitrogen at a partial pressure of oxygen of approximately 10⁻⁶ atmospheres to reoxidize the dielectric without oxidizing the underlying metal foil. The fired dielectric thickness was approximately 1.3 micrometers.

After removal from the furnace, copper electrodes varying in size from 1 mm by 1 mm to 10 mm by 10 mm were formed on the dielectric by sputtering copper through a mask. All capacitor sizes had yields in excess of 90%. The 10 mm by 10 mm capacitors exhibited capacitance densities of between approximately 1 and 1.2 μF/cm² and dissipation factors of about 30%.

### Example 5

A 0.38 mol barium titanate dielectric precursor solution was prepared as described in Example 1, except that the dielectric precursor solution was doped with 0.4 mole % of manganese by adding 0.006 g of manganese acetate tetrahydrate to the barium acetate solution in the step S130 of the method shown in FIG. 1.

Samples were prepared using the process as discussed with regard to FIG. 2. For each sample, a first layer of the dielectric precursor solution was deposited by spin coating on to a 2 inch by 2 inch, 25 micrometers thick, nickel foil obtained from All Foils. The coating speed was 3000 rpm. The dielectric precursor solution was then dried in air for 7 minutes at 250° C. The dried dielectric precursor layer was then prefired for 10 minutes at 450° C. in a moist nitrogen/forming gas mixture that was created by bubbling a mixture of nitrogen and forming gas (99% nitrogen and 1% hydrogen) through a water bath at approximately 20° C. to create a gas atmosphere with a partial pressure of water vapor of about between 0.02 and 0.03 atmospheres. The hydrogen content in the nitrogen was adjusted to give between 0.015% to 0.02% hydrogen in nitrogen. Measurement of the partial pressure of oxygen at the temperatures used for the prefire process was not accurate, but the moist gas mixture was estimated to give a partial pressure of oxygen of approximately 10⁻¹² atmospheres. The process of spin coating deposition, drying and prefiring at 450° C. was repeated nine more times after the first layer to give a total of 10 layers.

The multiple dried and prefired dielectric precursor layers on the nickel foil were fired in a 6 inch internal diameter tube furnace at 900° C. for 20 minutes at peak temperature. Firing was undertaken under a dry atmosphere consisting of a mixture of nitrogen and forming gas (99% nitrogen 1% hydrogen). The flow rates of the nitrogen and forming gas into the furnace were adjusted to give approximately 10 liters per minute of nitrogen and 15-20 cubic centimeters (cc) per minute of forming gas to result in between 0.015% to 0.02% hydrogen in nitrogen. The partial pressure of oxygen at the firing temperature was approximately 10⁻¹⁴ atmospheres as measured by use of a zirconia cell placed inside the furnace. The ramp rate of the furnace during the heating phase was approximately 15° C. per minute. During the cooling process, the forming gas supply to the furnace was switched off at 600° C. so that the dielectric was exposed to pure nitrogen at a partial pressure of oxygen of approximately 10⁻⁶ atmospheres to reoxidize the dielectric without oxidizing the underlying nickel foil.

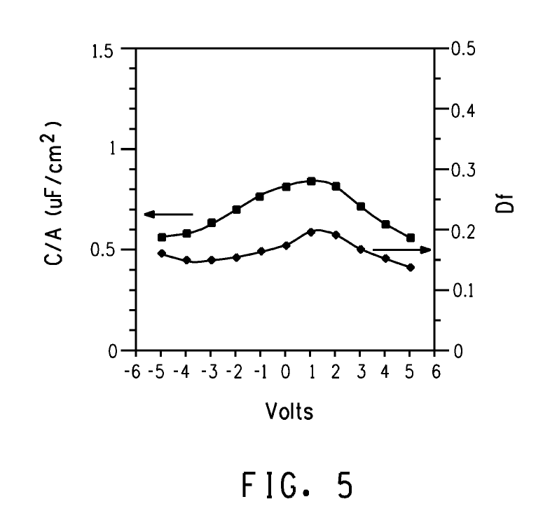

After removal from the furnace, copper electrodes varying in size from 1 mm by 1 mm to 10 mm by 10 mm were formed on the dielectric by sputtering copper through a mask. All capacitor sizes had yields in excess of 90%. The 10 mm by 10 mm capacitors exhibited capacitance densities of approximately 0.9 μF/cm². FIG. 5 shows capacitance density and dissipation factor as a function of voltage of a representative sample made according to this Example.

### Example 6

A 0.38 mol barium titanate dielectric precursor solution was prepared as described in Example 1, except that the dielectric precursor solution was doped with 0.07 mole % of manganese by adding 0.001 g of manganese acetate tetrahydrate to the barium acetate solution in the step S130 of the method shown in FIG. 1. The 0.38 mol barium titanate dielectric precursor solution was diluted to a 0.25 mol solution by use of additional acetic acid.

Samples were prepared using the process as discussed with regard to FIG. 2. For each sample, a first layer of the precursor solution was deposited by rod coating on to a 5 inch by 5 inch, 25 micrometers thick, nickel foil obtained from All Foils. The dielectric precursor solution was then dried in air for 5 minutes at 100° C. followed 7 minutes at 250° C. The dried thickness of the dielectric layer was approximately 0.1 micrometers. The dried dielectric precursor was then prefired for 10 minutes at 450° C. in a moist nitrogen/forming gas mixture that was created by bubbling a mixture of nitrogen and forming gas (99% nitrogen and 1% hydrogen) through a water bath at approximately 20° C. to create a gas atmosphere with a partial pressure of water vapor of between about 0.02 and 0.03 atmospheres. The hydrogen content in the nitrogen was adjusted to give between 0.015% to 0.02% hydrogen in nitrogen. Measurement of the partial pressure of oxygen at the temperatures used for the prefire process was not accurate but the moist gas mixture was estimated to give a partial pressure of oxygen of approximately 10⁻¹² atmospheres. The same process of rod coating deposition, drying and prefiring at 450° C. was repeated 11 more times after the formation and prefiring of the first layer to give a total of 12 layers.

The multiple dried and prefired dielectric precursor layers on the nickel foil were fired in a six inch internal diameter tube furnace at 900° C. for 30 minutes at peak temperature. Firing was undertaken under a dry atmosphere consisting of a mixture of nitrogen and forming gas (99% nitrogen 1% hydrogen). The flow rates of the nitrogen and forming gas into the furnace were adjusted to give approximately 10 liters per minute of nitrogen and 15-20 cubic centimeters (cc) per minute of forming gas to result in between 0.015% to 0.02% hydrogen in nitrogen. The partial pressure of oxygen at the firing temperature was approximately 10⁻¹⁴ atmospheres as measured by use of a zirconia cell placed inside the furnace. The ramp rate of the furnace during the heating phase was approximately 15° C. per minute. During the cooling process, the forming gas supply to the furnace was switched off at 600° C. so that the dielectric was exposed to pure nitrogen at a partial pressure of oxygen of approximately 10⁻⁶ atmospheres to reoxidize the dielectric without oxidizing the underlying nickel foil.

After removal from the furnace, copper electrodes varying in size from 1 mm by 1 mm to 10 mm by 10 mm were formed on the dielectric by sputtering copper through a mask. The capacitors of all of the sizes had yields in excess of 90%. The 10 mm by 10 mm capacitors exhibited capacitance densities of between approximately 0.7 and 1.0 μF/cm² and dissipation factors of between 3.5 and 8%.

### Example 7

A 0.38 mol barium titanate dielectric precursor solution was prepared as described in Example 1, except that the dielectric precursor solution was doped with 0.07 mole % of manganese by adding 0.001 g of manganese acetate tetrahydrate to the barium acetate solution in the step S130 of the method shown in FIG. 1. The 0.38 mol barium titanate dielectric precursor solution was diluted to a 0.25 mol solution by use of additional acetic acid.

Samples were prepared using the process as discussed with regard to FIG. 2. For each sample, a first layer of the precursor solution was deposited by rod coating on to a 5 inch by 5 inch, 25 micrometers thick, nickel foil obtained from All Foils. The precursor solution was then dried in air for 5 minutes at 100° C. followed by 7 minutes at 250° C. The dried dielectric precursor was then prefired at 450° C. for 10 minutes in a moist nitrogen/forming gas mixture that was created by bubbling a mixture of nitrogen and forming gas (99% nitrogen and 1% hydrogen) through a water bath at approximately 20° C. to create a gas atmosphere with a partial pressure of water vapor of between about 0.02 and 0.03 atmospheres. The hydrogen content in the nitrogen was adjusted to give between 0.015% to 0.02% hydrogen in nitrogen. Measurement of the partial pressure of oxygen at the temperatures used for the prefire process was not accurate but the moist gas mixture was estimated to give a partial pressure of oxygen of approximately 10⁻¹² atmospheres. The same process of rod coating deposition, drying and prefiring at 450° C. was repeated 11 more times after the first layer to give a total of 12 dielectric precursor layers.

The multiple dried and prefired dielectric precursor layers on the nickel foil were fired in a six inch internal diameter tube furnace at 850° C. for 30 minutes at peak temperature. Firing was undertaken under an atmosphere consisting of pure nitrogen. The partial pressure of oxygen at the firing temperature was measured to be approximately 10⁻⁶ atmospheres. The ramp rate of the furnace during the heating phase was approximately 15° C. per minute. During the cooling process, no reoxidation procedure was used.

After removal from the furnace, copper electrodes varying in size from 1 mm by 1 mm to 10 mm by 10 mm were formed on the dielectric by sputtering copper through a mask. All capacitor sizes had yields in excess of 90%. The 10 mm by 10 mm capacitors exhibited capacitance densities of between approximately 0.6 and 0.9 μF/cm².

### Example 8

A 0.38 mol barium titanate dielectric precursor solution was prepared as described in Example 1, except that the dielectric precursor solution was doped with 0.1 mole % of calcium by adding 0.002 g of calcium nitrate tetrahydrate to the barium acetate solution in the step S130 of the method shown in FIG. 1

Samples were prepared using the process as discussed with regard to FIG. 2. For each sample, a first layer of the dielectric precursor solution was deposited by spin coating on to the drum side of a 2 inch by 2 inch, ½ oz (18 micrometers thick), cleaned copper foil obtained from Oak Mitsui. The coating speed was 3000 rpm. The precursor solution was then dried in air for 7 minutes at 250° C. The dried precursor was then prefired for 10 minutes at 450° C. in a moist nitrogen/forming gas mixture that was created by bubbling a mixture of nitrogen and forming gas (99% nitrogen and 1% hydrogen) through a water bath at approximately 20° C. to create a gas atmosphere with a partial pressure of water vapor of about between about 0.02 and 0.03 atmospheres. The hydrogen content in the nitrogen was adjusted to give between 0.015% to 0.02% hydrogen in nitrogen. Measurement of the partial pressure of oxygen at the temperatures used for the prefire process was not accurate but the moist gas mixture was estimated to give a partial pressure of oxygen of approximately 10⁻¹² atmospheres. The same process of spin coating deposition, drying and prefiring at 450° C. was repeated nine more times after the first layer to give a total of 10 layers.

The multiple dried and prefired dielectric precursor layers on the copper foil were fired in a six inch internal diameter tube furnace at 950° C. for 20 minutes at peak temperature. Firing was undertaken under a dry atmosphere consisting of a mixture of nitrogen and forming gas (99% nitrogen 1% hydrogen). The flow rates of the nitrogen and forming gas into the furnace were adjusted to give approximately 10 liters per minute of nitrogen and 15-20 cubic centimeters (cc) per minute of forming gas to result in between 0.015% to 0.02% hydrogen in nitrogen. The partial pressure of oxygen at the firing temperature was approximately 10⁻¹⁴ atmospheres as measured by use of a zirconia cell placed inside the furnace. The ramp rate of the furnace during the heating phase was approximately 15° C. per minute. During the cooling process, the forming gas supply to the furnace was switched off at 600° C. so that the dielectric was exposed to pure nitrogen at a partial pressure of oxygen of approximately 10⁻⁶ atmospheres to reoxidize the dielectric without oxidizing the underlying copper foil.

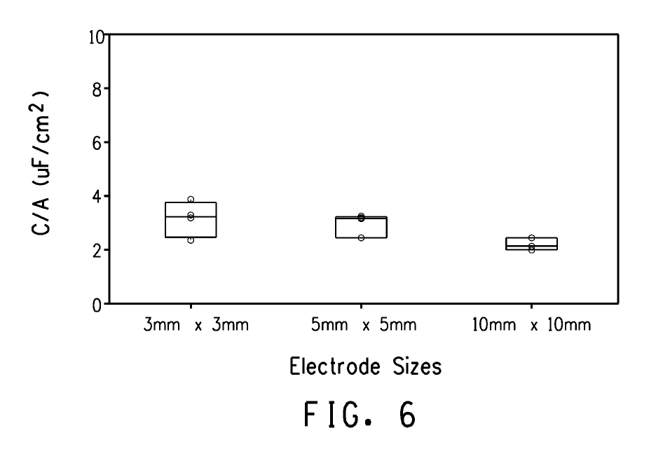

After removal from the furnace, copper electrodes varying in size from 1 mm by 1 mm to 10 mm by 10 mm were formed on the dielectric by sputtering copper through a mask. All capacitor sizes had yields of 100%. FIG. 6 shows the capacitance density obtained from the capacitors of three sizes. The 10 mm by 10 mm capacitors exhibited capacitance densities of between approximately 2.1 and 2.5 μF/cm² and dissipation factors of between 10 and 13%.

As illustrated in Example 1, the use of a conventional drying process only at 250° C. for each dielectric precursor layer on copper foil was shown to be not effective in achieving high yield in large area capacitors, most probably due primarily to insufficient residual organic material removal from the dielectric precursor film resulting in poor densification. Additionally, films with greater than 7 layers made from this processes exhibited substantial cracking after firing, probably as a result of excessive shrinkage of the films.

In Example 2, a prefire process was added for each dielectric precursor layer. Each dielectric precursor layer was prefired in air at 400° C. using nickel as the underlying foil. Prefiring in air at this temperature was feasible because the foil was nickel, but would not have been feasible for a copper foil as copper would severely oxidize. Firing was undertaken at 900° C. followed by a re-oxidation process. High yield was obtained but dissipation factors were extremely high (>100%) and capacitors could not take bias without failing. This suggested that air prefiring at 400° C. did not sufficiently remove residual organic material from the dielectric precursor film.

The influence of prefire temperature on capacitance density for dielectric precursor films on copper foil was evaluated in Example 3. Prefiring was undertaken in a moist reducing atmosphere which helped to avoid oxidizing the copper foil. The prefired layers were evaluated by X-ray diffraction as shown in FIG. 3. Micro-crystalline precipitates were observed in samples prefired at 550° C. and 650° C. After firing, yield was 90% and, as shown in FIG. 4, and the highest capacitance density was achieved when the prefire temperature was 450° C.

In Example 4, each layer of the dielectric precursor formed on a copper foil was prefired at 450° C. under a moist reducing atmosphere. The dielectric precursor and copper foil were subsequently fired followed by a re-oxidation step. Yield was high and dissipation factors were improved.

Example 5 and 6 used the same moist reducing prefire at 450° C. process as was used in Example 4, but nickel was used as the underlying metal foil. Different coating techniques were used for Example 4 and 5. Both processes exhibited good yield and good dissipation factors showing that the coating process was not a major influence. FIG. 5, shows capacitance density and dissipation factor data for a capacitor sample made according to Example 5.

In Example 7, capacitors on nickel foil were processed in a similar manner to Example 6, but firing was undertaken in pure nitrogen at 850° C. Capacitors exhibited high yield and good dissipation factors without a re-oxidation process. Re-oxidation was not necessary in this case, as the dielectric had been fired in an atmosphere that was sufficiently oxidizing to the dielectric. Such an atmosphere, however, is not feasible where the foil is copper foil.

In Example 8, a calcium doped sample on copper foil was prefired at 450° C. under a moist reducing atmosphere and firing was undertaken at 950° C. under a partial pressure of oxygen of approximately 10⁻¹⁴ atmospheres followed by a re-oxidation process. All capacitor sizes showed high yield and good dissipation factors.

The examples show that addition of a moist reducing atmosphere prefire process for capacitors on nickel and copper foil allows for high yield on each foil with acceptable electrical properties in large area capacitors, such as 10 mm by 10 mm area capacitors.

What is claimed is:

1. A method of making a dielectric, comprising:
providing a base metal foil;
forming a dielectric precursor layer over the base metal foil;
prefiring the dielectric precursor layer and base metal foil at a prefiring temperature in the range of 350 to 650° C. in a moist atmosphere comprising a reducing gas; and
firing the prefired dielectric precursor layer and base metal foil at a firing temperature in the range of 700 to 1200° C. in an atmosphere having an oxygen partial pressure of less than about 10⁻⁶ atmospheres to produce a dielectric.

2. The method of making a dielectric of claim 1 wherein the prefiring temperature is in the range of 350 to 500° C.

3. The method of making a dielectric of claim 1 wherein during the prefiring of the of the dielectric precursor layer, the reducing gas is selected from H₂ and CO.

4. The method of making a dielectric of claim 1 wherein during the prefiring of the of the dielectric precursor layer, the moist atmosphere has a partial pressure of water vapor of at least about 0.02 atmospheres;

5. The method of making a dielectric of claim 1 wherein the base metal foil is comprised of one or more metals selected from copper, nickel, invar, stainless steel and alloys thereof.

6. The method of making a dielectric of claim 1 wherein the forming of the dielectric precursor layer over the base metal foil comprises the steps of coating a film of a dielectric precursor solution on the base metal foil and drying the dielectric precursor solution.

7. The method of making a dielectric of claim 6 wherein the dielectric precursor solution is dried at a temperature between 100 and 300° C. until substantially all solvent in the dielectric precursor solution is removed.

8. The method of making a dielectric of claim 6 wherein the forming of a dielectric precursor layer over the base metal foil comprises the steps of coating a first layer of a dielectric precursor solution on the base metal foil, drying the first layer of dielectric precursor solution at a temperature between 100 and 300° C. to form a first dried dielectric precursor layer, coating an additional dielectric precursor solution layer over the dried first dielectric precursor layer, drying said additional dielectric precursor solution layer at a temperature between 100 and 300° C. to form an additional dried dielectric precursor layer over said first dried dielectric precursor layer.

9. The method of claim 1, wherein after prefiring of the dielectric precursor layer, an additional dielectric precursor layer is formed over the prefired dielectric precursor layer, and wherein said additional dielectric precursor layer is prefired at a temperature in the range of 350 to 650° C. in an atmosphere having a partial pressure of water vapor of at least about 0.02 atmospheres and comprising a reducing gas.

10. The method of claim 1, wherein the firing results in a dielectric comprising crystalline barium titanate or crystalline barium strontium titanate.

11. A method of making a capacitor, comprising:
providing a base metal foil;
forming a dielectric precursor layer over the base metal foil;
prefiring the dielectric precursor layer and base metal foil at a prefiring temperature in the range of 350 to 650° C. in an atmosphere having a partial pressure of water vapor of about at least 0.02 atmospheres and comprising a reducing gas;
firing the prefired dielectric precursor layer and base metal foil at an firing temperature in the range of 700 to 1200° C. in an atmosphere having an oxygen partial pressure of less than about 10⁻⁶ atmospheres to produce a dielectric; and
forming a second conductive layer over the dielectric, wherein the metal foil, the dielectric, and the second conductive layer form the capacitor.

12. The method of making a capacitor of claim 11 wherein the prefiring temperature is in the range of 350 to 500° C.

13. The method of making a capacitor of claim 11 wherein the reducing gas in the prefiring atmosphere is selected from H₂ and CO.

14. The method of making a capacitor of claim 11 wherein the base metal foil is comprised of one or more metals selected from copper, nickel, invar, stainless steel, and alloys thereof.

15. The method of making a capacitor of claim 11 wherein forming the dielectric precursor layer comprises providing a dielectric precursor solution comprising barium acetate and titanium isopropoxide or titanium butoxide.

16. The method of making a capacitor of claim 11 wherein the forming of a dielectric precursor layer over the base metal foil comprises the steps of coating a first layer of a dielectric precursor solution on the base metal foil, drying the first layer of dielectric precursor solution at a temperature between 100 and 300° C. to form a first dried dielectric precursor layer, coating additional dielectric precursor solution over the dried first dielectric precursor layer, drying said additional dielectric precursor solution at a temperature between 100 and 300° C. to form an additional dried dielectric precursor layer over said first dried dielectric precursor layer.

17. The method of making a capacitor of claim 11, wherein after the dielectric precursor layer is prefired, an additional dielectric precursor layer is formed over the prefired dielectric precursor layer, and wherein said additional dielectric precursor layer is prefired at a temperature in the range of 350 to 650° C. in a moist atmosphere having a having a partial pressure of water vapor of about at least 0.02 atmospheres and comprising a reducing gas before either dielectric precursor layer is fired.

18. The method of claims 11, wherein the fired dielectric is reoxidized at a temperature of between 400 and 700° C. in an atmosphere having a partial pressure of oxygen greater than about 10⁻⁶ atmospheres.

19. The method of claim 11, wherein the base metal foil is a copper foil and wherein the prefired dielectric precursor layer is fired in an atmosphere having a partial pressure of oxygen less than about 10⁻⁸ atmospheres in a temperature range of 800 to 1050° C.

20. The method of claims 19, wherein the fired dielectric is reoxidized at a temperature of between 400 and 700° C. in an atmosphere having a partial pressure of oxygen greater than about 10⁻⁶ atmospheres.

21. The method of claim 11, wherein the base metal foil is a nickel foil and wherein the prefired dielectric precursor layer is fired at a temperature between 700° C. and about 1200° C. in an atmosphere having a partial pressure of oxygen less than about 10⁻⁶ atmospheres.

22. The method of claim 11, wherein the firing results in a dielectric comprising crystalline barium titanate or crystalline barium strontium titanate.

23. The method of claim 11 wherein the area of the capacitor is greater than 10 mm².

24. The method of claim 11 wherein the area of the capacitor is greater than 80 mm².

25. The method of claim 11 wherein the area of the capacitor is greater than 400 mm².

26. The method of claim 11, further comprising the steps of selectively etching one or more of the metal foil and the second conductive layer to create a plurality of individual capacitor units wherein each of the individual capacitor units can function as a separate capacitor.

27. The method of claim 26 wherein the plurality of individual capacitor units comprises at least twenty individual capacitor units embedded in a printed wiring board.

28. The method of claim 27 wherein the plurality of individual capacitor units comprises at least one hundred individual capacitor units embedded in a printed wiring board.

29. The method of claim 27 wherein the plurality of individual capacitor units comprises at least five hundred individual capacitor units embedded in a printed wiring board.
